(19) United States
(12) Patent Application Publication
(10) Pub. No.: US 2011/0102203 A1
(43) Pub. Date: May 5, 2011

(54) PHONE WITH QWERTY KEYPAD HAVING A CONNECTION FOR LINKING TO A COMPUTER

(76) Inventor: Mark CARAVELLA, Las Vegas, NV (US)

(21) Appl. No.: 12/611,813

(22) Filed: Nov. 3, 2009

(51) Int. Cl. H03M 11/00

(52) U.S. Cl. 341/22

(57) ABSTRACT

A keyboard unit has a keyboard being approximately two thumb lengths in width and one thumb length in height to allow thumb typing. At least one connector is provided to couple the keyboard to a computer system

### FIELD OF THE INVENTION

This invention relates to keyboards and, more specifically, to a cellular telephone, Personal Digital Assistant (PDA), and the like (hereinafter cellular phone) which has a QWERTY keyboard, the cellular phone connectable to a computer for allowing a user to input data to the computer using the QWERTY keyboard of the cellular phone.

### BACKGROUND OF THE INVENTION

Text messaging is a term used to describe the exchange of brief written messages between cellular phones over a cellular network. While the term most often refers to messages sent using the Short Message Service (SMS), it has been extended to include messages containing image, video, and sound content, such as Multimedia Message Service (MMS) messages. Individual messages are referred to as “text messages” or “texts”.

Texting is extremely popular worldwide. In the United States alone, the average number of text messages sent per subscriber per month was 188. In the third quarter of 2006, at least 12 billion text messages crossed AT&T′s network, up almost 15 percent from the preceding quarter. The design of full QWERTY keypads on cellular phones has further increased the ease and popularity of texting. However, because the size of the QWERTY keypads on the cellular phones, most people send text messages by using their thumbs to type the message. This technique is commonlying referred to as thumbing or thumb typing. Because many younger people have grown up texting, these people are able to type faster using their thumbs then typing using standard techniques. In fact, the World Record for texting is entering 160 characters in 41.52 seconds. Since many younger people are use to thumbing, they have a difficult time typing on a standard computer keyboard. Due to the larger size of the keyboard on a computer system, people are unable to thumb type and thus many people have a difficult time typing on a standard computer keyboard

Therefore, a need exists to provide a system and method to overcome the above problem. The system and method would provide a reliable way for allowing a user to input data to a computer system using a QWERTY keyboard of the cellular phone.

### SUMMARY OF THE INVENTION

A keyboard unit has a keyboard being approximately two thumb lengths in width and one thumb length in height to allow thumb typing. At least one connector is provided to couple the keyboard to a computer system.

A keyboard unit has a QWERTY keyboard being approximately two thumb lengths in width and one thumb length in height to allow thumb typing. A wired connector is provided to couple the keyboard unit to a computer system.

A keyboard unit has a QWERTY keyboard being approximately two thumb lengths in width and one thumb length in height to allow thumb typing. A wired connector is provided to couple the keyboard to a computer system. The wired connector is one of a USB connector, an IEEE 1394 connector, serial or parallel connector, or the like. A wireless port is provided to wirelessly couple the keyboard to the computer system.

The present invention is best understood by reference to the following detailed description when read in conjunction with the accompanying drawings.

### BRIEF DESCRIPTION OF THE DRAWINGS

FIG. 1 is a perspective view of a QWERTY keyboard of a cellular phone;

FIG. 2 is a simplified schematic of the QWERTY keyboard of a cellular phone of FIG. 1; and

FIG. 3 is perspective view showing the interconnection between the cellular phone and the computer system.

Common reference numerals are used throughout the drawings and detailed description to indicate like elements.

### DETAILED DESCRIPTION

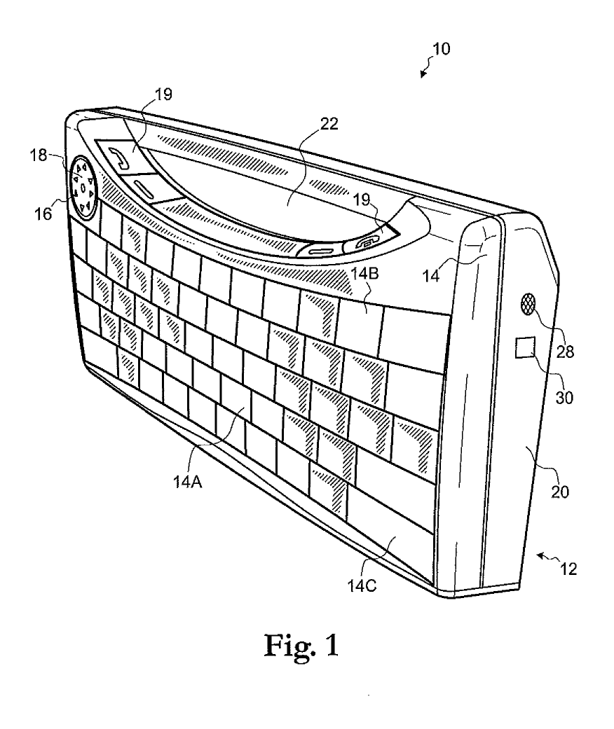

Referring to FIG. 1, a hand sized QWERTY keyboard 10 is shown. The QWERTY keyboard 10 may be part of a cellular phone 12, PDA, handheld game console, or the like (hereinafter cellular phone 12). The QWERTY keyboard 10 is approximately two thumb lengths wide and one thumb length tall. The QWERTY keyboard 10 may be a full alphabet keyboard 14. As used herein, the term “full alphabet keyboard” refers to a keyboard containing individual input keys for the major characters or letters of a language. For example, a full alphabet keyboard for the English language includes individual input keys 14A for the letters A through Z. The full alphabet keyboard may additionally include input keys 14B for inputting different numbers (i.e., 0 through 9). The full alphabet keyboard may additionally include input keys 14C that are function keys (i.e., a shift key, enter key). Commonly used symbols (i.e., $, %, &, etc.) may be additional input keys or may be entered by pressing a combination of input keys 14C and input keys 14A and or 14B. Thus, for example, the symbol “*” may be entered by pressing an input keys 14C such as the shift key and an input key 14B such as the number “8”.

The QWERTY keyboard 10 may further include a navigation mouse and or joystick 16 (hereinafter navigation mouse 16). The navigation mouse 16 may further have input buttons 18. The input buttons 18 may be used to input and or enter data. The input buttons 18 may be similar in functionality as the left and right click buttons on a standard computer mouse. The QWERTY keyboard 10 may have one or more menu keys 19. The menu keys 19 may be used to control different features of the cellular phone 14. The QWERTY keyboard 10 may have other input interfaces known to those skilled in the art.

In accordance with one embodiment, the QWERTY keyboard 10 is coupled to a cellular phone 12. The cellular phone 12 may have a housing 20. The housing 20 may be used to protect the internal components of the cellular phone 12. The cellular phone 14 may further have a display 22, a speaker, a microphone, and or other interface mechanisms.

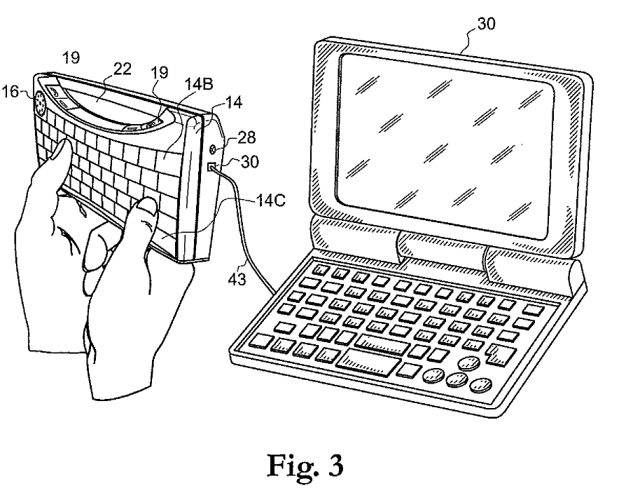

The housing 20 may have an output port 28 and or an output connector 30. The output port 28 and or an output connector 30 may be used to couple the QWERTY keyboard 10 and or cellular phone 14 to a computer system 32 (FIG. 3). This may allow the cellular phone 12 to input data to the computer system 32. The output port 28 may be an infrared port or other type of wireless interface. The output connector 30 may be a USE connector, an IEEE 1394 connector, serial or parallel connector, or the like.

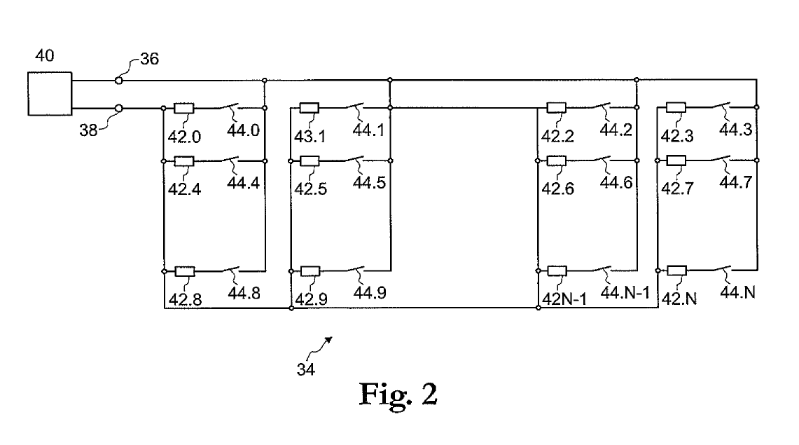

Referring to FIG. 2, details of the keyboard circuitry 34 is shown. The keyboard circuitry 34 generally has interconnects 36 and 38. The interconnects 36 and 38 may be used to couple the keyboard circuitry 34 to a processor 40. The processor 40 may be used to read signals from the keyboard circuitry 34 and to output a corresponding alphanumeric character to the display 22 or to the computer system 32 via the output port 28 and or the output connector 30.

The keyboard circuitry 34 may have an array of resistive elements 42.0 to 42.N. The resistive elements 42.0 to 42.N may each have a different ohm value. In one embodiment, the resistive elements 42.0 to 42.N may range from 1 K to 200 K ohms. A bias voltage may be coupled to the interconnects 32 and 34 and to the array of resistive elements 42.0 to 42.N. The resistive elements 42.0 to 42.N are each connected in series with a single key contact switch 44.0 to 44.N respectively and to a common ground. When any one of the key contact switches 44.0 to 44.N is pressed, the corresponding resistor 42.0 to 42.N in the array is connected to ground thus forming a resistor divider circuit. The values of resistive elements 42.0 to 42.N are arranged to give a different discrete voltage from the resistor divider circuit when the different key contact switches 44.0 to 44.N are pressed. These discrete voltages are monitored by the processor 44 to determine the corresponding alphanumeric character to be shown of the display 22 or to the computer system 32.

Referring now to FIG. 3, in operation, the QWERTY keyboard 10 may be coupled to the computer system wirelessly via the output port 28 or via a wired connection 43 through the output connector 30. If a wireless connection is used, the user may have to press a one or more input keys 14A-14C and or a menu key 19. The user may also have to press a one or more input keys 14A-14C and or a menu key 19 for a wired connection. Alternatively, the processor 44 may monitor the output port 28 or output connector 30 to see if any connection has been made.

Once connected, the user may use the QWERTY keyboard 10 to enter alphanumeric characters to the computer system 32. The user may hold the QWERTY keyboard 10 in the fingers of both hands 50 so that the thumbs 52 extend across the width of the QWERTY keyboard 10. The user may thumb type by pressing one or more desired input keys 14A-14C. By pressing a desired input key 14A-14C, a corresponding key contact switch 44.0 to 44.N is pressed. Pressing key contact switch 44.0 to 44.N causes a corresponding resistor 42.0 to 42.N in the array to connect to ground thus forming a resistor divider circuit that generates a discrete voltage level. The discrete voltage level is monitored by the processor 44 to determine the corresponding alphanumeric character to be shown of the display 22 or to the computer system 32.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. A keyboard unit comprising:
a keyboard being approximately two thumb lengths in width and one thumb length in height to allow thumb typing; and
at least one connector to couple the keyboard to a computer system.

2. A keyboard unit in accordance with claim 1 wherein the keyboard is a QWERTY keyboard.

3. A keyboard unit in accordance with claim 1 wherein the connector is a wireless port to wirelessly couple the keyboard to the computer system.

4. A keyboard unit in accordance with claim 3 wherein the wireless port is an infrared port.

5. A keyboard unit in accordance with claim 1 wherein the connector is a wired connector.

6. A keyboard unit in accordance with claim 5 wherein the wired connector is one of a USB connector, an IEEE 1394 connector, serial or parallel connector, or the like.

7. A keyboard unit in accordance with claim 1 wherein the keyboard comprises a resistor divider circuit that generates discrete voltage levels for each key of the keyboard.

8. A keyboard unit in accordance with claim 7 wherein the resistor divider circuit comprises:
a plurality of switches; and
a resistive element coupled to each of the plurality of switches, wherein touching one key closes a corresponding switch and couples a corresponding resistive element to ground to generate a corresponding voltage level.

9. A keyboard unit in accordance with claim 8 further comprising a processor coupled to the resistor divider circuit to monitor voltage levels from the resistor divider circuit to determine a corresponding alphanumeric character related to each voltage level.

10. A keyboard unit comprising:
a QWERTY keyboard being approximately two thumb lengths in width and one thumb length in height to allow thumb typing; and
a wired connector to couple the QWERTY keyboard unit to a computer system.

11. A keyboard unit in accordance with claim 9 further comprising a wireless port to wirelessly couple the QWERTY keyboard to the computer system.

12. A keyboard unit in accordance with claim 11 wherein the wireless port is an infrared port.

13. A keyboard unit in accordance with claim 10 wherein the wired connector is one of a USB connector, an IEEE 1394 connector, serial or parallel connector, or the like.

14. A keyboard unit in accordance with claim 10 wherein the QWERTY keyboard comprises:
a resistor divider circuit that generates discrete voltage levels for each key of the QWERTY keyboard; and
a processor coupled to the resistor divider circuit for monitoring the discrete voltage levels and to generate a corresponding alphanumeric symbol for each discrete voltage level.

15. A keyboard unit in accordance with claim 14 wherein the resistor divider circuit comprises:
a plurality of switches; and
a resistive element coupled to each of the plurality of switches, wherein touching one key closes a corresponding switch and couples a corresponding resistive element to ground to generate a corresponding voltage level.

16. A keyboard unit comprising:
a QWERTY keyboard being approximately two thumb lengths in width and one thumb length in height to allow thumb typing; and
a wired connector to couple the QWERTY keyboard to a computer system; and
a wireless port to wirelessly couple the QWERTY keyboard to the computer system;
wherein the wired connector is one of a USB connector, an IEEE 1394 connector, serial or parallel connector, or the like.

17. A keyboard unit in accordance with claim 16 wherein the QWERTY keyboard comprises a resistor divider circuit that generates discrete voltage levels for each key of the keyboard.

18. A keyboard unit in accordance with claim 17 wherein the resistor divider circuit comprises:
a plurality of switches; and
a resistive element coupled to each of the plurality of switches, wherein touching one key closes a corresponding switch and couples a corresponding resistive element to ground to generate a corresponding voltage level.

19. A keyboard unit in accordance with claim 18 further comprising a processor coupled to the resistor divider circuit to monitor voltage levels from the resistor divider circuit to determine a corresponding alphanumeric character related to each voltage level.

20. A keyboard unit in accordance with claim 16 wherein the wireless port is an infrared port.
